(19) United States
(12) Patent Application Publication
(10) Pub. No.: US 2024/0331998 A1
(43) Pub. Date: Oct. 3, 2024

(54) SUBSTRATE PROCESSING METHOD AND SUBSTRATE PROCESSING SYSTEM

(71) Applicant: Tokyo Electron Limited, Tokyo (JP)

(72) Inventors: Susumu HAYAKAWA, Kikuchi-gun, Kumamoto (JP); Kazuya IKEUE, Kikuchi-gun, Kumamoto (JP); Tomohiro KANEKO, Kikuchi-gun, Kumamoto (JP)

(21) Appl. No.: 18/711,900

(22) PCT Filed: Nov. 15, 2022
(86) PCT No.: PCT/JP2022/042339

§ 371 Date: May 21, 2024

(30) Foreign Application Priority Data
Nov. 29, 2021 (JP) 2021-193343

(51) Int. Cl. H01L 21/02; B24B 7/22; B24B 41/00; B24B 51/00

(52) U.S. Cl. CPC H01L 21/02013; B24B 7/228; B24B 41/005; B24B 51/00

(57) ABSTRACT

A substrate processing method of processing a substrate includes: grinding a first surface of the substrate; and grinding, after grinding the first surface, a second surface of the substrate opposite to the first surface. A first grinding mark extending from a center of the first surface toward an outer periphery thereof in a gently curved manner is formed when the first surface is ground, a second grinding mark extending from a center of the second surface toward an outer periphery thereof in a gently curved manner is formed when the second surface is ground, and a curving direction of the first grinding mark and a curving direction of the second grinding mark are opposite when viewed through from one of the first surface or the second surface.

### TECHNICAL FIELD

The various aspects and embodiments described herein pertain generally to a substrate processing method and a substrate processing system.

### BACKGROUND

Patent Document 1 discloses a substrate processing system that grinds both surfaces of a substrate. The substrate processing system includes a first main surface grinding apparatus configured to hold the substrate from below with a first main surface of the substrate facing upwards and also configured to grind the first main surface of the substrate; and a second main surface grinding apparatus configured to hold the ground first main surface of the substrate from below with a second main surface of the substrate facing upwards and also configured to grind the second main surface of the substrate.

### PRIOR ART DOCUMENT

Patent Document 1: International Publication No. WO 2020/039802

### DISCLOSURE OF THE INVENTION

### Problems to be Solved by the Invention

Exemplary embodiments provide a technique capable of suppressing damage to a substrate after being subjected to grinding of both surfaces thereof.

### Means for Solving the Problems

In one exemplary embodiment, A substrate processing method of processing a substrate includes: grinding a first surface of the substrate; and grinding, after grinding the first surface, a second surface of the substrate opposite to the first surface. A first grinding mark extending from a center of the first surface toward an outer periphery thereof in a gently curved manner is formed when the first surface is ground, a second grinding mark extending from a center of the second surface toward an outer periphery thereof in a gently curved manner is formed when the second surface is ground, and a curving direction of the first grinding mark and a curving direction of the second grinding mark are opposite when viewed through from one of the first surface or the second surface.

### Effect of the Invention

According to the exemplary embodiments, it is possible to suppress the grinding damage to the substrate after being subjected to the grinding of both surfaces thereof.

### BRIEF DESCRIPTION OF THE DRAWINGS

FIG. 1 is a plan view illustrating a schematic configuration of a wafer processing system according to an exemplary embodiment.

FIG. 2 is a side view illustrating a schematic configuration of a first grinding module (second grinding module).

FIG. 3 is an explanatory diagram illustrating a state in which a first surface (second surface) of a wafer is ground by the first grinding module (second grinding module).

FIG. 4 is an explanatory diagram illustrating a state in which a grinding mark is formed on the first surface (second surface) of the wafer by the first grinding module.

FIG. 5 is an explanatory diagram illustrating a state in which a grinding mark is formed on the first surface (second surface) of the wafer by the first grinding module.

FIG. 6 is an explanatory diagram illustrating a state in which a grinding mark is formed on the first surface (second surface) of the wafer by the second grinding module.

FIG. 7 is an explanatory diagram illustrating a state in which the first surface (second surface) of the wafer is ground by a grinding apparatus.

FIG. 8A to FIG. 8C are explanatory diagrams illustrating grinding marks formed on both surfaces of a wafer in a comparative example.

FIG. 9A to FIG. 9C are explanatory diagrams illustrating the grinding marks formed on both surfaces of the wafer according to the exemplary embodiment.

FIG. 10 is a flowchart illustrating main processes of a wafer processing.

FIG. 11 is an explanatory diagram illustrating a state in which a first surface (second surface) of a wafer is ground by a grinding apparatus according to another exemplary embodiment.

FIG. 12 is a plan view illustrating a schematic configuration of a wafer processing system according to yet another exemplary embodiment.

### DETAILED DESCRIPTION

In a manufacturing process for a semiconductor device, both a front surface and a rear surfaces of a disk-shaped silicon piece cut out from a single crystalline silicon ingot with a wire saw or the like are ground to be flattened. Then, a silicon wafer (hereinafter, sometimes simply referred to as “wafer”) is manufactured.

Here, in order to improve productivity and reduce the number of processes involved in the wafer manufacturing, it is necessary to minimize grinding damage in the grinding process. Conventionally, however, suppressing this grinding damage has yet to be considered.

The present disclosure provides a technique capable of suppressing grinding damage to a substrate when grinding both surfaces of the substrate. Hereinafter, a wafer processing system as a substrate processing system and a wafer processing method as a substrate processing method according to an exemplary embodiment will be described with reference to the accompanying drawings. Further, in the present specification and the drawings, parts having substantially the same functions and configurations will be assigned same reference numerals, and redundant description thereof will be omitted.

In a wafer processing system 1 according to the present exemplary embodiment, a processing of improving in-surface thickness uniformity is performed on a wafer W as a substrate cut out from an ingot. Hereinafter, cut surfaces of the wafer W are referred to as a first surface Wa and a second surface Wb. The first surface Wa is a surface opposite to the second surface Wb. Also, the first surface Wa and the second surface Wb may sometimes be collectively referred to as one surface of the wafer W.

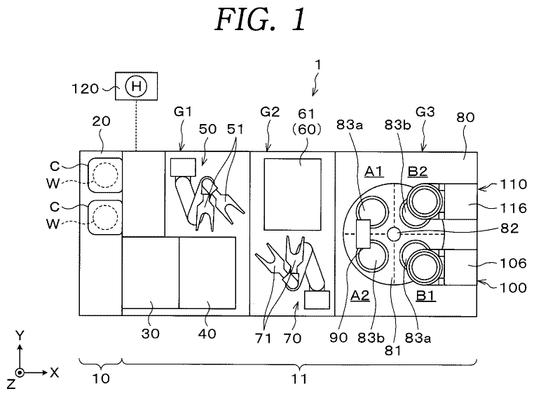

As shown in FIG. 1, the wafer processing system 1 has a configuration in which a carry-in/out station 10 and a processing station 11 are connected as one body. In the carry-in/out station 10, a cassette C capable of accommodating therein a plurality of wafers W is carried to/from the outside, for example. The processing station 11 is equipped with various types of processing apparatuses configured to perform required processings on the wafer W. Further, in the following description, the plurality of wafers W accommodated in the cassette C will be referred to as one lot.

The carry-in/out station 10 is equipped with a cassette placing table 20. In the shown example, a plurality of, e.g., two cassettes C can be arranged in a row on the cassette placing table 20 in the Y-axis direction. Here, the number of the cassettes C placed on the cassette placing table 20 is not limited to the example of the present exemplary embodiment, and may be selected as required.

The processing station 11 is provided with, for example, three processing blocks G1 to G3. The first processing block G1, the second processing block G2, and the third processing block G3 are arranged in this order from the negative X-axis side (carry-in/out station 10 side) toward the positive X-axis side.

The first processing block G1 is equipped with etching apparatuses 30, cleaning apparatus 40, and a wafer transfer device 50. The etching apparatuses 30 are provided in, for example, three levels in a vertical direction on the carry-in/out station 10 side of the first processing block G1. The cleaning apparatuses 40 are provided in, for example, three levels in the vertical direction on the positive X-axis side of the etching apparatuses 30. The wafer transfer device 50 is disposed on the positive Y-axis side of the etching apparatuses 30 and the cleaning apparatuses 40. Here, the number and the layout of the etching apparatus 30, the cleaning apparatus 40 and the wafer transfer device 50 are not limited to the shown example.

The etching apparatus 30 is configured to etch the first surface Wa after being ground or the second surface Wb after being ground. For example, an etching liquid (chemical liquid) is supplied to the first surface Wa or the second surface Wb after being ground to wet-etch the corresponding first surface Wa or the second surface Wb after being ground. The etching liquid may be, by way of non-limiting example, HF, HNO₃, H₃PO₄, TMAH, Choline, KOH, etc.

The cleaning apparatus 40 is configured to clean the first surface Wa after being ground or the second surface Wb after being ground. For example, a brush is brought into contact with the first surface Wa or the second surface Wb to scrub-clean the first surface Wa or the second surface Wb. Also, a pressurized cleaning liquid may be used to clean the first surface Wa or the second surface Wb. Further, the cleaning apparatus 40 may be configured to clean the first surface Wa and the second surface Wb simultaneously when cleaning the wafer W.

The wafer transfer device 50 has, for example, two transfer arms 51 each configured to hold and transfer the wafer W. Each transfer arm 51 is configured to be movable in a horizontal direction and a vertical direction and pivotable around a horizontal axis and a vertical axis. The wafer Transfer device 50 is configured to transfer the wafer W to/from the cassette C on the cassette placing table 20, the etching apparatus 30, the cleaning apparatus 40 to be described later, a transition device 60 to be described later, and an inverting device 61 to be described later.

The second processing block G2 is provided with the transition device 60, the inverting device 61, and a wafer transfer device 70. The transition device 60 and the inverting device 61 are stacked in this order from the bottom in the vertical direction, for example. The wafer Transfer device 70 is disposed on the negative Y-axis side of the transition device 60 and the inverting device 61. Here, the number and the layout of the transition device 60, the inverting device 61, and the wafer Transfer device 70 are not limited to the shown example.

The transition device 60 temporarily places therein the wafer W in order to transfer the wafer W. The inverting device 61 is configured to invert the first surface Wa and the second surface Wb of the wafer W in the vertical direction.

The wafer transfer device 70 has, for example, two transfer arms 71 each configured to hold and transfer the wafer W. Each transfer arm 71 is configured to be movable in a horizontal direction and a vertical direction and pivotable around a horizontal axis and a vertical axis. Also, the wafer transfer device 70 is configured to transfer the wafer W to/from the cleaning apparatus 40, the transition device 60, the inverting device 61, and a grinding apparatus 80 to be described later.

The third processing block G3 is equipped with the grinding apparatus 80. The number and the layout of the grinding apparatus 80 are not limited to the shown example.

The grinding apparatus 80 has a rotary table 81. The rotary table 81 is configured to be rotatable about a vertical rotation center line 82 by a rotating mechanism (not shown). Provided on the rotary table 81 are four chucks 83 as holders each configured to attract and hold the wafer W. Among the four chucks 83, two first chucks 83a are provided to grind the first surface Wa and are configured to attract and hold the second surface Wb. These two first chucks 83a are arranged at point-symmetrical positions with the rotation center line 82 therebetween. The remaining two second chucks 83b are provided to grind the second surface Wb, and are configured to attract and hold the first surface Wa. These two second chucks 83b are also arranged at point-symmetrical positions with the rotation center line 82 therebetween. That is, the first chucks 83a and the second chucks 83b are alternately arranged in a circumferential direction.

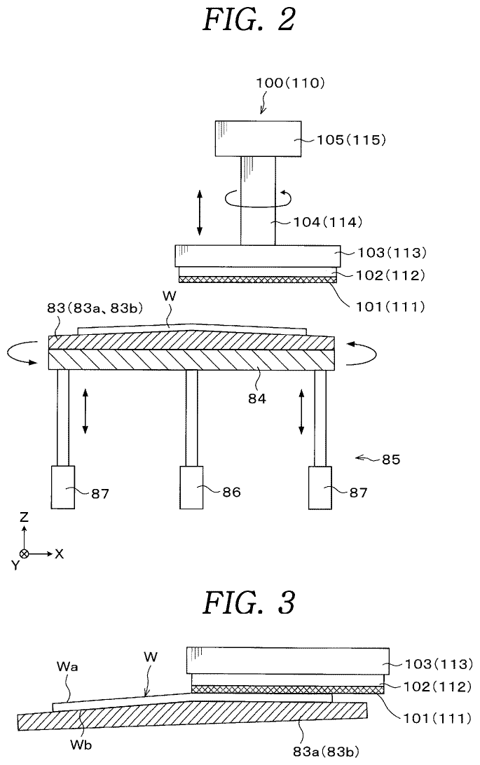

A porous chuck, for example, is used as the chuck 83. A surface of the chuck 83, that is, a holding surface, on which the wafer W is held, has a convex shape with a central portion protruding higher than an end portion when viewed from the side. Although this protrusion of the central portion of the chuck 83 is actually minute, it is rather exaggerated in FIG. 2 for clarity of description.

As depicted in FIG. 2, the chuck 83 is held by a chuck base 84. The chuck base 84 is provided with an inclination adjuster 85 configured to adjust relative inclination between the chuck 83 and grinding whetstones 101 and 111 belonging to grinding modules 100 and 110 to be described later, respectively. The inclination adjuster 85 has a fixed shaft 86, and a plurality of, for example, two elevation shafts 87 provided on a bottom surface of the chuck base 84. Each elevation shaft 87 is configured to be extensible and contractible, and serves to move the chuck base 84 up and down. This inclination adjuster 85 moves one end of an outer peripheral portion of the chuck base 84 in a vertical direction by the elevation shaft 87 with respect to the other end (position corresponding to the fixed shaft 86) of the outer peripheral portion of the chuck base 84, thus allowing the chuck 83 and chuck base 84 to be tilted. In this way, it is possible to adjust the relative inclination between the surface of the chuck 83 and surfaces of the grinding whetstones 101 and 111 of the grinding modules 100 and 110 at processing positions B1 and B2 to be described later.

Further, the configuration of the inclination adjuster 85 is not limited to the shown example, and any of various configurations may be adopted as long as the relative angle (parallelism) of the surface of the chuck 83 with respect to the surfaces of the grinding whetstones 101 and 111 can be adjusted.

As shown in FIG. 1, the four chucks 83 can be moved to delivery positions A1 and A2 and the processing positions B1 and B2 as the rotary table 81 is rotated. Further, each of the four chucks 83 is configured to be rotatable around a vertical axis by a rotating mechanism (not shown).

The first delivery position A1 is a position on the negative X-axis and positive Y-axis side of the rotary table 81, where the wafer W is delivered to/from the first chuck 83a when the wafer W is ground. The second delivery position A2 is a position on the negative X-axis and negative Y-axis side of the rotary table 81, where the wafer W is delivered to/from the second chuck 83b when the wafer W is ground. A thickness measurer 90 configured to measure the thickness of the wafer W after being ground is provided at the delivery positions A1 and A2. The thickness measurer 90 measures the thickness of the wafer W at multiple points to acquire an in-surface thickness distribution of the wafer W. The thickness measurer 90 may have any configuration. For example, it may be equipped with, for example, a non-contact sensor (not shown).

The first processing position B1 is a position on the positive X-axis and negative Y-axis side of the rotary table 81, and the first grinding module 100 as a first grinder is disposed thereat. The first grinding module 100 is configured to grind either the first surface Wa or the second surface Wb of the wafer W held by the first chuck 83a. The second processing position B2 is a position on the positive X-axis and positive Y-axis side of the rotary table 81, and the second grinding module 110 as a second grinder is disposed thereat. The second grinding module 110 is configured to grind either the first surface Wa or the second surface Wb of the wafer W held by the second chuck 83b.

In addition, in the present exemplary embodiment, the rotary table 81 serves as a transfer mechanism configured to transfer the wafer W held by the first chuck 83a to the first grinding module 100 to locate the wafer W therein, or transfer the wafer W held by the second chuck 83b to the second grinding module 110 to locate the wafer W therein.

As illustrated in FIG. 2, the first grinding module 100 includes a grinding wheel 102 having the grinding whetstone 101 of an annular shape on a bottom surface thereof; a mount 103 supporting the grinding wheel 102; a spindle 134 configured to rotate the grinding wheel 102 via the mount 103; and a driver 105 having, for example, a motor (not shown) embedded therein. Further, the first grinding module 100 is configured to be movable in a vertical direction along a supporting column 106 shown in FIG. 1.

The second grinding module 110 has the same configuration as the first grinding module 100. That is, the second grinding module 110 has a grinding wheel 112 equipped with the grinding whetstone 111 of an annular shape, a mount 113, a spindle 114, a driver 115, and a supporting column 116.

The above-described wafer processing system 1 is provided with a control device 120 as shown in FIG. 1. The control device 120 is, for example, a computer equipped with a CPU, a memory, etc., and has a program storage (not shown). The program storage stores therein a program for controlling a processing of the wafer W in the wafer processing system 1. The program may have been recorded on a computer-readable recording medium H, and may be installed from the recording medium H into the control device 120. The recording medium H may be transitory or non-transitory.

Now, grinding of the wafer W by the first grinding module 100 and grinding of the wafer W by the second grinding module 110 will be described.

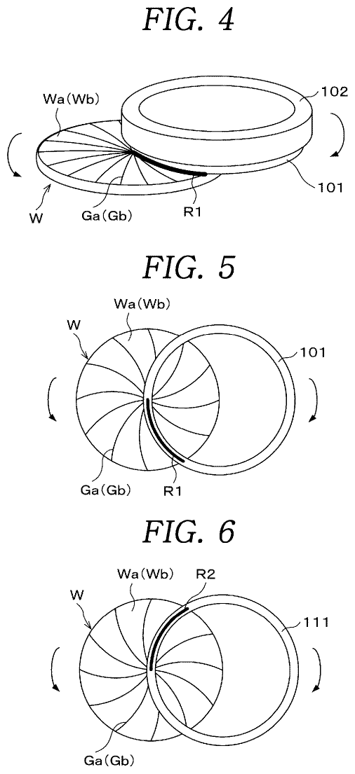

As shown in FIG. 3, each of the chucks 83a and 83b has a convex shape at a central portion of its holding surface for the wafer W. For this reason, when grinding the first surface Wa of the wafer W by using the first grinding module 100, the first chuck 83a is tilted such that the first surface Wa of the wafer W held by the first chuck 83a becomes parallel to a surface of the grinding whetstone 101. Further, as indicated by bold lines in FIG. 4 and FIG. 5, a portion of the annular grinding whetstone 101 comes into contact with the wafer W as a first processing point R1. More specifically, the annular grinding whetstone 101 comes into contact with a portion of the wafer W ranging from a center to an outer end thereof in an arc line shape. In this state, by respectively rotating both the first chuck 83a and the grinding wheel 102, the entire first surface Wa is ground. The same applies when grinding the second surface Wb of the wafer W by using the first grinding module 100.

In addition, when grinding the first surface Wa by using the first grinding module 100, a first grinding mark Ga, which is a so-called saw mark, that extends from a center toward an outer periphery in a gently curved manner is formed on the first surface Wa. Also, when grinding the second surface Wb by using the first grinding module 100, a second grinding mark Gb that extends from a center toward an outer periphery in a gently curved manner is formed on the second surface Wb. Each of the first grinding mark Ga and the second grinding mark Gb has curved convex portions that are continuous in a clockwise direction, and in the following description, this curving direction may sometimes be referred to as “clockwise direction.”

As shown in FIG. 3, when grinding the first surface Wa of the wafer W by using the second grinding module 110 as well, the second chuck 83b is tilted such that the first surface Wa of the wafer W held by the second chuck 83b becomes parallel to a surface of the grinding whetstone 111. Further, as indicated by a bold line in FIG. 6, a portion of the annular grinding whetstone 111 comes into contact with the wafer W as a second processing point R1. More specifically, the annular grinding whetstone 111 comes into contact with a portion of the wafer W ranging from the center to the outer end thereof in an arc line shape. In this state, by respectively rotating both the second chuck 83b and the grinding wheel 112, the entire first surface Wa is ground. The same applies when grinding the second surface Wb of the wafer W by using the second grinding module 110.

Further, when grinding the first surface Wa by using the second grinding module 110, a first grinding mark Ga that extends from a center toward an outer periphery in a gently curved manner is formed on the first surface Wa. Also, when grinding the second surface Wb by using the second grinding module 110, a second grinding mark Gb that extends from a center toward an outer periphery in a gently curved manner is formed on the second surface Wb. Each of the first grinding mark Ga and the second grinding mark Gb has curved convex portions that are continuous in a counterclockwise direction, and in the following description, this curving direction may sometimes be referred to as “counterclockwise direction.”

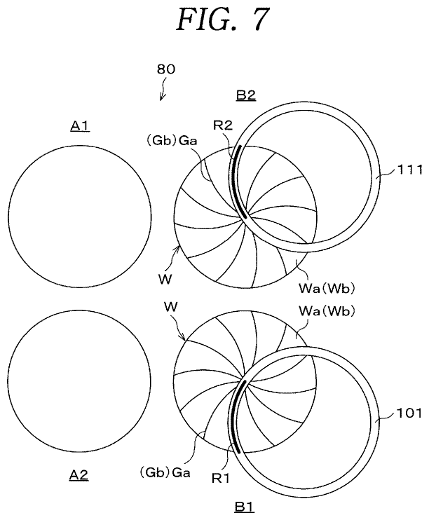

As shown in FIG. 7, when the relative positional relationship between the first chuck 83a and the grinding whetstone 101 is different from the relative positional relationship between the second chuck 83b and the grinding whetstone 111, the position of the first processing point R1 in the case of using the first grinding module 100 is different from the position of the second processing point R2 in the case of using the second grinding module 110. For this reason, the curving direction of the grinding marks Ga and Gb in the case of using the first grinding module 100 and the curving direction of the grinding marks Ga and Gb in the case of using the second grinding module 110 are opposite to each other on the same surface of the wafer W.

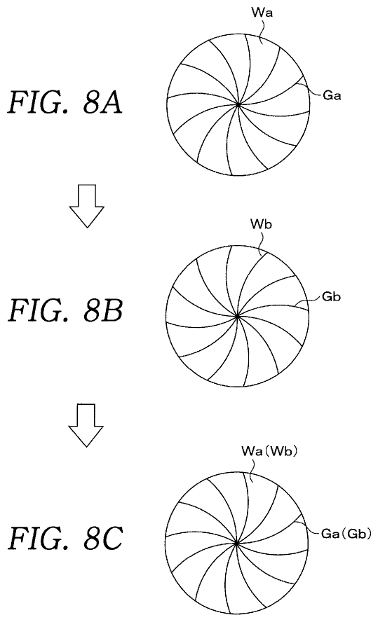

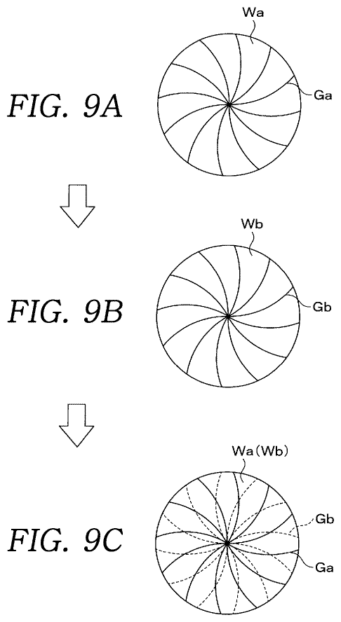

Here, when the surfaces Wa and Wb of the one wafer W are ground by the different grinding modules 110 and 110, the grinding marks Ga and Gb overlap. For example, by grinding the first surface Wa with the first grinding module 100, the first grinding mark Ga in the clockwise direction is formed as shown in FIG. 8A. Then, by grinding the second surface Wb with the second grinding module 110, the second grinding mark Gb in the counterclockwise direction is formed as shown in FIG. 8B. As a result, these grinding marks Ga and Gb overlap when viewed through from one surface of the wafer W. In this case, grinding damage is likely to increase.

In contrast, in the present exemplary embodiment, the surfaces Wa and Wb of the one wafer W are ground by the same grinding module 100 (110). For example, by grinding the first surface Wa with the first grinding module 100, the first grinding mark Ga in the clockwise direction is formed as shown in FIG. 9A. Thereafter, by grinding the second surface Wb with the first grinding module 100, the second grinding mark Gb in the clockwise direction is formed as shown in FIG. 9B. In this way, if the curving directions of the grinding marks Ga and Gb are the same, the grinding marks Ga and Gb on the wafer W cross each other and do not overlap, as shown in FIG. 9C. In this case, the grinding damage can be suppressed as compared to the case where the grinding marks Ga and Gb overlap. Likewise, when each of the surfaces Wa and Wb of the one wafer W is ground by the second grinding module 110, the grinding marks Ga and Gb do not overlap when viewed through from one surface of the wafer W. Thus, the same effect as stated above can be achieved.

As described above, the present inventors have found out that there is a correlation between the curving directions of the grinding marks Ga and Gb and the grinding damage, and also found out that the grinding damage can be suppressed by appropriately controlling the directions of the grinding marks Ga and Gb.

Now, a wafer processing performed by using the wafer processing system 1 configured as described above will be explained. In the present exemplary embodiment, a required processing is performed on the wafer W that has been cut out from the ingot with the wire saw or the like and wrapped.

First, the cassette C accommodating therein the plurality of wafers W is placed on the cassette placing table 20 of the carry-in/out station 10. In the cassette C, each wafer W is accommodated with the first surface Wa facing upwards and the second surface Wb facing downwards.

Then, the wafer W in the cassette C is taken out by the wafer transfer device 50 and transferred to the transition device 60.

Thereafter, the wafer W is transferred to the grinding apparatus 80 by the wafer transfer device 70, and delivered to the first chuck 83a at the first delivery position A1. Here, the second surface Wb of the wafer W is attracted to and held by the first chuck 83a.

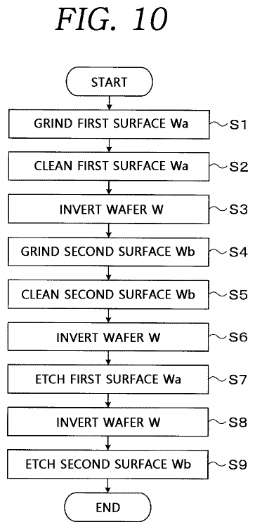

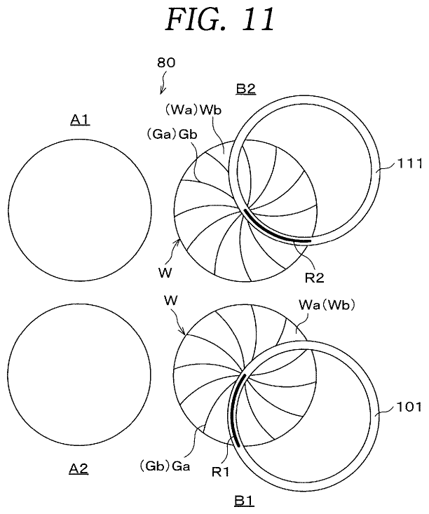

Next, the rotary table 81 is rotated to move the wafer W to the first processing position B1. Then, the first surface Wa of the wafer W is ground by the first grinding module 100 (process S1 in FIG. 10). At this time, the first grinding mark Ga in the clockwise direction is formed on the first surface Wa, as shown in FIG. 9A.

Thereafter, the rotary table 81 is rotated to move the wafer W to the first delivery position A1.

Then, the wafer W is transferred to the cleaning apparatus 40 by the wafer transfer device 70. In the cleaning apparatus 40, the first surface Wa of the wafer W is cleaned (process S2 in FIG. 10).

Next, the wafer W is transferred to the inverting device 61 by the wafer transfer device 70. In the inverting device 61, the first surface Wa and the second surface Wb of the wafer W are inverted in the vertical direction (process S3 in FIG. 10). That is, the wafer W is turned upside down with the second surface Wb facing upwards and the first surface Wa facing downwards.

Subsequently, the wafer W is transferred to the grinding apparatus 80 by the wafer transfer device 70, and delivered to the first chuck 83a at the first delivery position A1. Here, the first surface Wa of the wafer W is attracted to and held by the first chuck 83a.

Next, the rotary table 81 is rotated to move the wafer W to the first processing position B1. Then, the second surface Wb of the wafer W is ground by the first grinding module 100 (process S4 in FIG. 10). At this time, the second grinding mark Gb in the clockwise direction is formed on the second surface Wb as shown in FIG. 9B. Since the curving directions of the grinding marks Ga and Gb are the same, the grinding marks Ga and Gb do not overlap when viewed through from one surface, as illustrated in FIG. 9C.

Thereafter, the rotary table 81 is rotated to move the wafer W to the second delivery position A2.

Then, the wafer W is transferred to the cleaning apparatus 40 by the wafer transfer device 70. In the cleaning apparatus 40, the second surface Wb of the wafer W is cleaned (process S5 in FIG. 10).

Next, the wafer W is transferred to the inverting device 61 by the wafer transfer device 50. In the inverting device 61, the first surface Wa and the second surface Wb of the wafer W are inverted in the vertical direction (process S6 in FIG. 10). That is, the wafer W is turned upside down with the first surface Wa facing upwards and the second surface Wb facing downwards.

Subsequently, the wafer W is transferred to the etching apparatus 30 by the wafer transfer device 50. In the etching apparatus 30, the first surface Wa of the wafer W is etched by an etching liquid (process S7 in FIG. 10). As a result, a grinding residue, a grinding damage, and the like remaining on the first surface Wa are removed.

Then, the wafer W is transferred to the inverting device 61 by the wafer transfer device 50. In the inverting device 61, the first surface Wa and the second surface Wb of the wafer W are inverted in the vertical direction (process S8 in FIG. 10). That is, the wafer W is turned upside down with the second surface Wb facing upwards and the first surface Wa facing downwards.

Thereafter, the wafer W is transferred to the etching apparatus 30 by the wafer transfer device 50. In the etching apparatus 30, the second surface Wb of the wafer W is etched by an etching liquid (process S9 in FIG. 10). As a result, a grinding residue, a grinding damage, and the like remaining on the second surface Wb are removed.

Afterwards, the wafer W after being subjected to all the required processes is transferred to the cassette C on the cassette placing table 20 by the wafer transfer device 50. In this way, the series of processes of the wafer processing in the wafer processing system 1 are completed. Further, the wafer W on which the required processing has been performed in the wafer processing system 1 may be additionally subjected to polishing outside the wafer processing system 1.

According to the above-described exemplary embodiment, since the surfaces Wa and Wb of the one wafer W are ground by the same first grinding module 100, the grinding marks Ga and Gb on the wafer W can be formed so as not to overlap each other. Therefore, the grinding damage can be suppressed. As a result, the conventionally required flattening and smoothing process for removing the grinding damage becomes unnecessary or can be reduced, making it possible to improve productivity and reduce the number of processes involved in the wafer manufacturing.

In addition, in the above-described exemplary embodiment, the plurality of wafers W accommodated in the same cassette C may be transferred one by one to the first grinding module 100 and the second grinding module 110 alternately.

For example, if the plurality of wafers W accommodated in the same cassette C are all transferred to the first grinding module 100 and the first surface Wa and the second surface Wb of each wafer W are ground by using this first grinding module 100, the second grinding module 110 is not driven until a plurality of wafers W in the next lot are ground. That is, the first grinding module 100 and the second grinding module 110 cannot be used in parallel, resulting in poor wafer processing efficiency.

Meanwhile, for the plurality of wafers W accommodated in the same cassette C, one wafer W is transferred to the first grinding module 100, and the next wafer W is transferred to the second grinding module 110, for example. That is, the control device 120 performs a control over the transfer of the wafer W in the grinding apparatus 80, and the wafers W in the same cassette C are transferred to the first grinding module 100 and the second grinding module 110 alternately. In this case, the first grinding module 100 and the second grinding module 110 can be used in parallel, so that the wafers W can be processed efficiently and the throughput of the processing of the wafers W can be improved.

Now, a grinding apparatus 80 according to another exemplary embodiment will be explained. As depicted in FIG. 11, in the grinding apparatus 80, the first grinding module 100 (grinding wheel 102) and the second grinding module 110 (grinding wheel 112) are positioned with respect to the chuck 83 so that the same grinding marks are formed by the first processing point R1 and the second processing point R2. As a result, the curving direction of the grinding marks Ga and Gb in the case of using the first grinding module 100 and the curving direction of the grinding marks Ga and Gb in the case of using the second grinding module 110 become identical. That is, when grinding the first surface Wa or second surface Wb of the wafer W by using the first grinding module 100, the first grinding mark Ga or second grinding mark Ga in the clockwise direction is formed. Likewise, when grinding the first surface Wa or second surface Wb of the wafer W by using the second grinding module 110, the first grinding mark Ga or second grinding mark Ga in the clockwise direction is formed.

In this case, for the one wafer W, the wafer W is moved to the first processing position B1 in the process S1, and the first surface Wa of the wafer W is ground by the first grinding module 100. As a result, the first grinding mark Ga in the clockwise direction is formed on the first surface Wa.

Afterwards, for the same wafer W, the wafer W is moved to the second processing position B2 in the process S3, and the second surface Wb of the wafer W is ground by the second grinding module 110. As a result, the second grinding mark Gb in the clockwise direction is formed on the second surface Wb. In this way, the control device 120 controls the rotary table 81 as a transfer mechanism along with the first and second grinding modules 100 and 110.

According to the present exemplary embodiment, when the wafer W is viewed through from one surface, the grinding marks Ga and Gb cross each other and do not overlap. As a result, the grinding damage can be suppressed.

Further, the grinding marks Ga and Gb when using the first grinding module 100 and the grinding marks Ga and Gb when using the second grinding module 110 may be counterclockwise. That is, in the grinding apparatus 80 in which the first grinding module 100 (grinding wheel 102) and the second grinding module 110 (grinding wheel 112) are disposed with respect to the chuck 83 so that the curving directions of the grinding marks Ga and Gb are in one direction, the same effect as stated above can be obtained. Since the plurality of wafers W accommodated in the same cassette C are first transferred to the first grinding module 100 and then transferred to the second grinding module 110 in succession, continuous processing is enabled, so that the throughput of the processing of the wafers W can be improved.

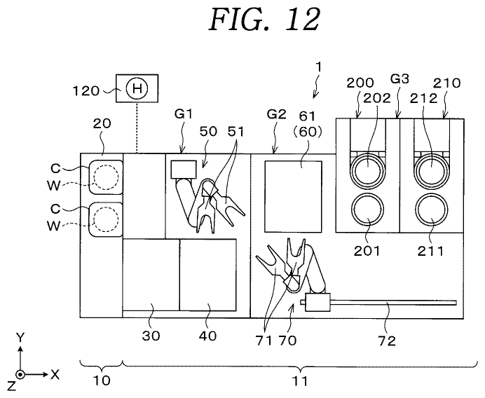

Now, a wafer processing system 1 according to yet another exemplary embodiment will be described. As shown in FIG. 12, the wafer processing system 1 has a plurality of, for example, two grinding apparatuses 200 and 210 instead of the grinding apparatus 80 of the above-described exemplary embodiment. The grinding apparatuses 200 and 210 are arranged in this order from the negative X-axis side toward the positive X-axis side. The wafer transfer device 70 is configured to be moved along a rail 72 elongated in the X-axis direction to transfer the wafer W to the grinding apparatuses 200 and 210.

The first grinding apparatus 200 has a chuck 201 configured to attract and hold the wafer W, and a grinding module 202. The chuck 201 is configured to be movable between a delivery position and a processing position by a moving mechanism (not shown). At the delivery position, the wafer W is delivered to/from the chuck 201 when it is ground. The grinding module 202 is disposed at the processing position.

The grinding module 202 has the same configuration as the grinding modules 100, 110 and 130 of the above-described exemplary embodiment, and serves to grind the first surface Wa of the wafer W held by the chuck 201. The grinding module 202 is disposed with respect to the chuck 201 such that the first grinding mark Ga in the clockwise direction is formed on the first surface Wa of the wafer W.

The second grinding apparatus 210 has the same configuration as the first grinding apparatus 200, and includes a chuck 211 and a grinding module 212. The grinding module 212 is configured to grind the second surface Wb of the wafer W held by the chuck 211. The grinding module 212 is disposed with respect to the chuck 211 such that a second grinding mark Gb in the clockwise direction is formed on the second surface Wb of the wafer W.

In this case, for the one wafer W, the first surface Wa is ground in the first grinding apparatus 200 in the process S1, and the first grinding mark Ga in the clockwise direction is formed on the first surface Wa. Thereafter, for the same wafer W, the second surface Wb is ground in the second grinding apparatus 210 in the process S3, and the second grinding mark Gb in the clockwise direction is formed on the second surface Wb.

According to the present exemplary embodiment, when the wafer W is viewed through from one surface, the grinding marks Ga and Gb cross each other and do not overlap. As a result, the grinding damage can be suppressed.

Additionally, it is assumed that the grinding mark is formed on the wafer W in advance from a previous processing before the wafer W is carried into the wafer processing system 1. In this case, if the curving direction of the grinding mark is known in advance, the transfer of the wafer W may be controlled such that the grinding mark in the opposite direction is formed on the same surface. Alternatively, an imaging device (not shown) configured to image one surface of the wafer W may be provided inside the second grinding apparatus 210, and the grinding module 212 may be set according to the imaged first grinding mark Ga.

In the above-described exemplary embodiments, the first grinding mark Ga formed on the first surface Wa of the wafer W and the second grinding mark Gb formed on the second surface Wb are controlled not to overlap. However, the method of the present disclosure may also be applicable to a case of grinding one surface of the wafer W in multiple stages. For example, in two-stage single-surface grinding, a first grinding mark Ga heading to the right is formed in the first stage of the grinding of the first surface Wa, and a first grinding mark Ga heading to the left is formed in the second stage of the grinding of the first surface Wa. As a result, on the first surface Wa, the grinding marks Ga of the first and second stages do not overlap, so that the grinding damage can be suppressed.

In addition, when the curving direction of the first grinding mark Ga formed by using the first grinding apparatus 200 is known in advance, the wafer W may be transferred to the grinding module 212 of the second grinding apparatus 210 such that the first grinding mark Ga in the opposite direction to the known curving direction is formed.

In addition, in double-surface grinding performed by, for example, two stages, based on the curving direction of the grinding marks Ga and Gb formed by the first stage of the double-surface grinding in the grinding apparatus of the first stage, the curving direction of the grinding marks Ga and Gb formed by the second stage of the double-surface grinding in the grinding apparatus of the second stage is set such that the grinding damage is minimized.

For example, when the grinding marks Ga and Gb formed by the first stage of the double-surface grinding do not overlap, the grinding marks Ga and Gb formed by the second stage of the double-surface grinding are made to cross each other without overlapping and, also, to cross the grinding marks Ga and Gb of the first stage.

Further, for example, when the grinding marks Ga and Gb formed by the first stage of the double-surface grinding overlap, the grinding marks Ga and Gb formed by the second stage of the double-surface grinding cross the grinding mark Ga or the grinding mark Gb of one surface formed by the first stage of the double-surface grinding, and the grinding marks Ga and Gb of the second stage overlap each other.

In addition, for example, when the grinding marks Ga and Gb formed by the first stage of the double-surface grinding overlap, a contribution rate to the grinding damage may be different on the first surface Wa and the second surface Wb. By way of example, when the surface with a relatively small contribution rate to the grinding damage is the first surface Wa, the first grinding mark Ga formed by the first stage of the grinding and the first grinding mark Ga formed by the second stage of the grinding are made to overlap on the first surface Wa. On the other hand, when the surface that contributes largely to the grinding damage is the second surface Wb, the second grinding mark Gb formed by the first stage of the grinding and the second grinding mark Gb formed by the second stage of the grinding are made to cross each other and not to overlap on second surface Wb.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
80: Grinding apparatus
120: Control device
Ga: First grinding mark
Gb: Second grinding mark

1. A substrate processing method of processing a substrate, comprising:
grinding a first surface of the substrate; and
grinding, after grinding the first surface, a second surface of the substrate opposite to the first surface,
wherein a first grinding mark extending from a center of the first surface toward an outer periphery thereof in a gently curved manner is formed when the first surface is ground,
a second grinding mark extending from a center of the second surface toward an outer periphery thereof in a gently curved manner is formed when the second surface is ground, and
a curving direction of the first grinding mark and a curving direction of the second grinding mark are opposite when viewed through from one of the first surface or the second surface.

2. The substrate processing method of claim 1,
wherein the grinding of the first surface and the grinding of the second surface are performed by a grinding apparatus,
the grinding apparatus includes:
a first grinder configured to grind one surface of the substrate such that a curving direction of a grinding mark is in a first direction;
a second grinder configured to grind one surface of the substrate such that a curving direction of a grinding mark is in a second direction opposite to the first direction; and
a transfer mechanism configured to dispose the substrate in the first grinder and the second grinder, and
wherein the grinding of the first surface of the substrate and the grinding of the second surface of the substrate are performed by disposing the substrate in a preset one of the first grinder or the second grinder with the transfer mechanism.

3. The substrate processing method of claim 2,
wherein the substrate includes multiple substrates, and
the multiple substrates in a cassette are transferred one by one to the first grinder and the second grinder alternately.

4. The substrate processing method of claim 1,
wherein the grinding of the first surface and the grinding of the second surface are performed by a grinding apparatus including multiple grinders configured to grind one surface of the substrate such that curving directions of grinding marks are in one direction, and
the grinding of the first surface of the substrate and the grinding of the second surface of the substrate are performed by transferring the substrate to different grinders.

5. The substrate processing method of claim 1,
wherein double-surface grinding of the first surface and the second surface is performed in two stages, and
based on curving directions of grinding marks formed by a first stage of the double-surface grinding, curving directions of grinding marks formed by a second stage of the double-surface grinding is determined.

6. The substrate processing method of claim 5,
wherein when the grinding marks formed by the first stage of the double-surface grinding do not overlap when viewed through from one surface, the grinding marks formed by the second stage of the double-surface grinding do not overlap, either, when viewed through from one surface.

7. The substrate processing method of claim 5,
wherein when the grinding marks formed by the first stage of the double-surface grinding overlap when viewed through from one surface,
the grinding marks formed by the first stage of the double-surface grinding and the grinding marks formed by the second stage of the double-surface grinding overlap each other on a surface with a small contribution rate to grinding damage, and
the grinding marks formed by the first stage of the double-surface grinding and the grinding marks formed by the second stage of the double-surface grinding do not overlap on a surface with a large contribution rate to the grinding damage.

8. A substrate processing system configured to process a substrate, comprising:
a grinding apparatus configured to grind one surface of the substrate;
a transfer device configured to transfer the substrate to the grinding apparatus; and
a control device and a program storage including a program,
wherein the grinding apparatus grinds a first surface of the substrate,
the grinding apparatus grinds a second surface of the substrate opposite to the first surface,
a first grinding mark extending from a center of the first surface toward an outer periphery thereof in a gently curved manner is formed when the first surface is ground,
a second grinding mark extending from a center of the second surface toward an outer periphery thereof in a gently curved manner is formed when the second surface is ground, and
the program storage and the program are configured, with the control device, to control the grinding apparatus and the transfer device such that a curving direction of the first grinding mark and a curving direction of the second grinding mark are opposite when viewed through from one surface.

9. The substrate processing system of claim 8,
wherein the grinding apparatus comprises:
a holder configured to hold the substrate;
a first grinder configured to grind one surface of the substrate held by the holder such that a curving direction of a grinding mark is in a first direction;
a second grinder configured to grind one surface of the substrate held by the holder such that a curving direction of a grinding mark is in a second direction opposite to the first direction; and
a transfer mechanism configured to transfer the substrate held by the holder to the first grinder and the second grinder, and
the control device performs a control of transferring the substrate to a preset one of the first grinder or the second grinder when grinding the first surface of the substrate and grinding the second surface of the substrate.

10. The substrate processing system of claim 9,
wherein the substrate includes multiple substrates, and the control device controls the transfer device and the transfer mechanism to transfer the multiple substrates in a cassette one by one to the first grinder and the second grinder alternately.

11. The substrate processing system of claim 8,
wherein the grinding apparatus comprises:
a holder configured to hold the substrate;
multiple grinders configured to grind one surface of the substrate held by the holder such that curving directions of grinding marks are in one direction; and
a transfer mechanism configured to transfer the substrate held by the holder to the multiple grinders, and
when grinding the first surface of the substrate and grinding the second surface of the substrate, the control device performs a control of transferring the substrate to different grinders.
